(19) United States
(12) Patent Application Publication
(10) Pub. No.: US 2009/0127601 A1
(43) Pub. Date: May 21, 2009

(54) Image Sensor and Method for Manufacturing the Same

(76) Inventor: Il Ho SONG, Cheongju-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/263,952

(22) Filed: Nov. 3, 2008

(30) Foreign Application Priority Data
Nov. 19, 2007 (KR) 10-2007-0117700

(51) Int. Cl. H01L 31/062; H01L 21/00

(52) U.S. Cl. 257/294; 438/70; 257/E31.062; 257/E21.001

(57) ABSTRACT

An image sensor may include a device isolating layer and a photodiode on a substrate; a first dielectric layer on the photodiode; a first micro lens on the first dielectric layer; a second dielectric layer on the first micro lens; a color filter on the second dielectric layer; and a second micro lens on the color filter.

The present application claims the benefit under 35 U.S.C. §119 of Korean Patent Application No. 10-2007-0117700, filed Nov. 19, 2007, which is hereby incorporated by reference in its entirety.

### FIELD OF THE INVENTION

Embodiments of the present invention relate to an image sensor and a method for manufacturing the same.

### BACKGROUND

A microlens (ML) in a CMOS image sensor according to the related art is formed by coating an ML photoresist (ML PR) on a color filter array and then exposing the ML photoresist.

The method according to the related art leads to a problem due to a reduction of the pixel size as the technology decreases from 0.25 to 0.13 micron minimum line widths in CMOS image sensor (CIS) products. In other words, as the pixel size is reduced, the surface area receiving light is reduced. As the surface area receiving light is reduced relative to the total surface area, the fill factor of the device is reduced.

According to the related art, as pixel size is reduced, the size of the ML is reduced. In order to form the reduced ML, the thickness of the PR is lowered. As the thickness of the PR is lowered, striation may occur due to a defect in the coating. The two problems (i.e., reduction of the fill factor and striation) should be essentially solved or mitigated.

### SUMMARY OF THE INVENTION

It is an object of the present invention to provide an image sensor and a method for manufacturing the same capable of solving or mitigating the problem of ML striation without decreasing a fill factor and/or a ML resist thickness, even when the pixel size is decreased.

Embodiments of the present invention provide an image sensor comprising a device isolating layer and a photodiode on a substrate; a first dielectric layer on the photodiode; a first micro lens on the first dielectric layer; a second dielectric layer on the first micro lens; a color filter on the second dielectric layer; and a second micro lens on the color filter.

Also, there is provided a method for manufacturing an image sensor according to embodiments of the present invention comprising: forming a device isolating layer and a photodiode on a substrate; forming a first dielectric layer on the photodiode; forming a first micro lens on the first dielectric layer; forming a second dielectric layer on the first micro lens; a color filter on the second dielectric layer; and a second micro lens formed on the color filter.

### BRIEF DESCRIPTION OF THE DRAWINGS

FIG. 1 is a cross-sectional view of an exemplary image sensor according to embodiments of the present invention.

FIG. 2 is a view showing simulation results of an exemplary image sensor according to embodiments of the present invention.

FIGS. 3 to 5 are cross-sectional views showing an exemplary method for manufacturing an image sensor according to embodiments of the present invention.

### DETAILED DESCRIPTION OF THE EMBODIMENTS

Hereinafter, an image sensor and a method for manufacturing the same according to embodiments of the present invention will be described with reference to the accompanying drawings.

In the description of various embodiments, it will be understood that when a layer (or film) is referred to as being ‘on’ another layer or substrate, it can be directly on another layer or substrate, or one or more intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

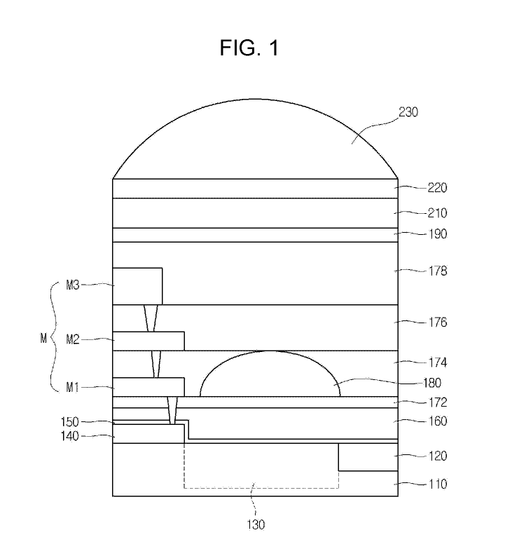

FIG. 1 is a cross-sectional view of an exemplary image sensor according to an embodiment of the present invention.

The exemplary image sensor may include a device isolating layer 120 and a photodiode 130 formed on a substrate 110; a first dielectric layer (e.g., inter metal dielectric) 172 formed on the photodiode 130; a first micro lens 180 formed on the first dielectric layer 172; a second dielectric layer (e.g., inter metal dielectric) 174 formed on the first micro lens 180; a color filter 210 formed on the second dielectric layer 174; and a second micro lens 230 formed on the color filter 210.

The first micro lens 180 (also known as an inner lens) may comprise a thermoset resin in an exemplary embodiment. For example, the thermoset resin may comprise an epoxy resin. Also, the first micro lens 180 may comprise a first seed micro lens 173 (see FIG. 5) and a thermal resin formed on the first seed micro lens 173. In one embodiment, the first seed micro lens 173 comprises a projection extending from the first dielectric layer 172, formed by patterning and partially etching the first dielectric layer 172.

Also, the first micro lens 180 can be formed on the first inter metal dielectric 172 and have a height corresponding to the first dielectric layer 172 (e.g., the first metallization layer including metal line M1), but is not limited thereto. In other words, the first micro lens 180 can be formed on an inter metal dielectric having a height corresponding to the second dielectric layer 174 (e.g., the second metallization layer including metal line M2), or a third dielectric layer 176 (e.g., the third metallization layer including metal line M3), etc. Meanwhile, non-explained structures including those identified by other reference numerals in FIG. 1 will be described in the following manufacturing method.

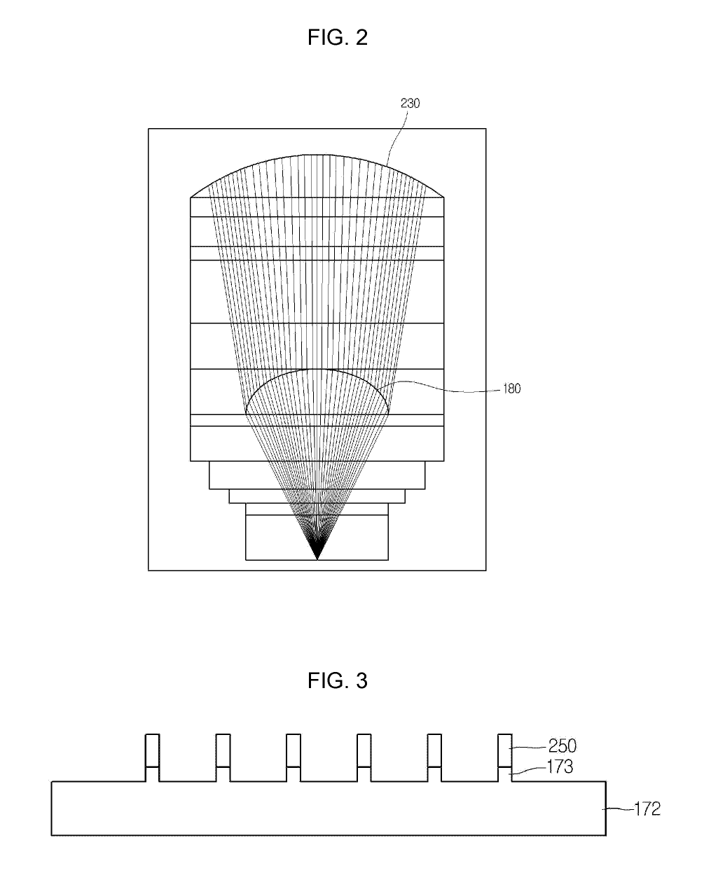

FIG. 2 is a view showing simulated results of an image sensor according to an embodiment of the present invention.

As shown in FIG. 2, even when an underlying device is small (see, e.g., inner lens 180), the problem of striation may be mitigated or prevented from occurring. Also, since the thickness of an upper micro lens (ML) can remain relatively thick, an area receiving light is wide, making it possible to increase a fill factor.

With the image sensor according to embodiments of the present invention, a self aligned inner lens may be formed using a thermal resin, such that the fill factor and the ML resist thickness is not reduced even when the pixel size is reduced, making it possible to solve or mitigate the ML striation problem.

Hereinafter, a method for manufacturing an image sensor according to embodiments of the present invention will be described with reference to FIG. 1 and FIGS. 3 to 5.

First, as shown in FIG. 1, an active region may be defined by forming the device isolating layer 120 on the substrate 110. Then, a gate 140 is formed on the active region and the photo diode 130 is formed by ion implantation. Thereafter, a first protective layer 150 is formed, and a PMD (pre-metal dielectric) 160 is formed thereon. The PMD 160 may comprise a lower-most, conformal etch stop layer (e.g., silicon nitride), a conformal buffer and/or gap-fill layer (e.g., silicon-rich oxide [SRO], TEOS [e.g., a silicon oxide formed by CVD from tetraethyl orthosilicate and oxygen], an undoped silicate glass [USG] or a combination thereof), a bulk dielectric layer (e.g., one or more silicon oxide layers doped with boron and/or phosphorus [BSG, PSG and/or BPSG]), and a capping layer (e.g., of TEOS, USG, a plasma silane [e.g., silicon dioxide formed by plasma-assisted CVD of silicon dioxide from silane and oxygen], or a combination thereof, such as a bilayer of plasma silane on USG or TEOS, or a bilayer of USG on TEOS).

Then, an inter metal dielectric (IMD) is formed on the PMD 160. For example, the first inter metal dielectric 172 is formed and the first micro lens 180, which is the inner lens, is formed on the first inter metal dielectric 172. The first IMD 172 may comprise a conventional etch stop layer (e.g., silicon nitride)

Hereinafter, a process for forming the first micro lens 180, which is the inner lens, will be described in detail.

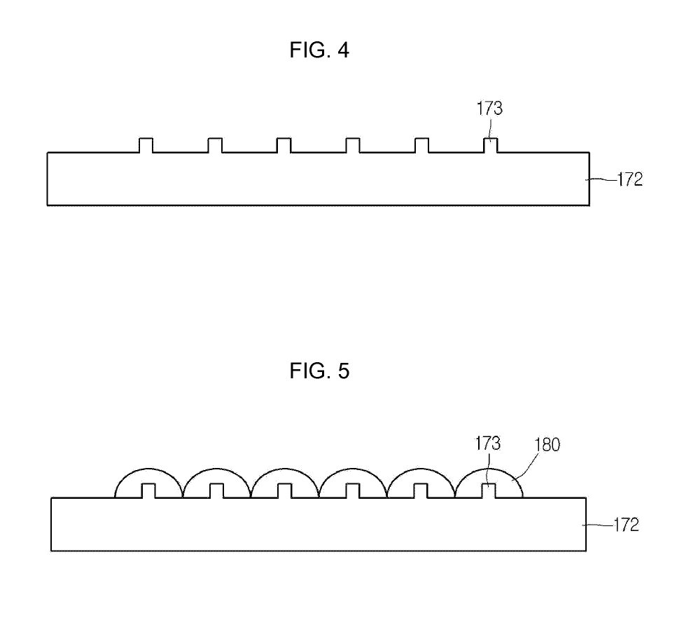

As shown in FIG. 3, the first inter metal dielectric 172 may be selectively etched using a photo resist pattern 250 to form the first seed micro lens 173. The etching process may be performed using Ar gas and/or CₓF_{y} gas(ses) (where x is an integer of from 1 to 5, and y is [2x+2], or when x is at least 2, 2x), and applying a voltage of 10 to 1000 W and a frequency of 13.56 MHz thereto. As shown in FIG. 4, the photo resist pattern 250 may then be removed (e.g., by conventional ashing).

Next, as shown in FIG. 5, an organic material may be formed on the first seed micro lens 173. For example, a thermal resin may be formed. The organic material may be formed by spin on deposition, drying and patterning (e.g., by photolithography and development). The patterned thermal resin may be subjected to a heat treatment to form a first micro lens 180 that is self-aligned. For example, the thermal resin may be subjected to the heat treatment at a temperature of about 130° C.±20° C., making it possible to form an inner lens that is self-aligned.

First micro lens 180 may be formed on the first inter metal dielectric 172 having a height corresponding to the second inter metal dielectric 174, but is not limited thereto. In other words, the first microlens 180 may be formed on the second inter metal dielectric 174 and have a height corresponding to the third IMD 176, etc.

Metal lines (e.g., M1, M2, M3) may each comprise sputter-deposited aluminum or aluminum alloy (e.g., Al with up to 4 wt. % Cu, up to 2 wt. % Ti, and/or up to 1 wt. % Si), on conventional adhesion and/or barrier layers (e.g., Ti and/or TiN, such as a TiN-on-Ti bilayer), and/or coveredby conventional adhesion, barrier, hillock suppression, and/or antireflective layers (e.g., Ti, TiN, WN, TiW alloy, or a combination thereof, such as a TiN-on-Ti bilayer or a TiW-on-Ti bilayer). The contacts/vias between the metal lines may each comprise tungsten (deposited by chemical vapor deposition [CVD]) or aluminum or aluminum alloy (e.g., as described above, deposited by sputtering), on conventional adhesion and/or barrier layers (e.g., Ti and/or TiN, such as a TiN-on-Ti bilayer). The Ti, TiN and TiW layers may be deposited by CVD or sputtering.

Referring to FIG. 1, the second inter metal dielectric 174 may be formed on the first micro lens 180. The second IMD 174 may comprise any of the dielectrics listed above for the PMD 160 and/or a stacked structure similar to the PMD 160, except that there may be no need for a lowermost etch stop layer, and the bulk dielectric may comprise a fluorosilicate glass (FSG), generally in place of a silicate glass doped with boron and/or phosphorous. In addition, a third inter metal dielectric 176, and even a fourth inter metal dielectric 178 may further be formed on the first micro lens 180, each of which may comprise any of the dielectrics listed above for the PMD 160 and/or second IMD 174, and have a stacked structure similar to the PMD 160 and/or second IMD 174, except that a lowermost etch stop layer may be included.

A color filter 210 may be formed on second inter metal dielectric 174, and an interposing second protective layer 190 may be formed therebetween. Thereafter, a planarization layer 220 is formed on the color filter 210 and a photo resist layer for a micro lens is formed on the planarization layer 220, making it possible to form the second micro lens 230 through a reflow.

Thus, a method for manufacturing an image sensor according to embodiments described above provides a self aligned inner lens formed using an organic material (e.g., thermal resin), making it possible to solve or mitigate the problem of ML striation without reducing a fill factor and/or ML resist thickness even when pixel size is decreased, thus improving a micro lens.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An image sensor comprising:
a device isolating layer and a photodiode on a substrate;
a first dielectric layer on the photodiode;
a first micro lens on the first dielectric layer;
a second dielectric layer on the first micro lens;
a color filter on the second dielectric layer; and
a second micro lens on the color filter.

2. The image sensor according to claim 1, wherein the first micro lens comprises an organic material.

3. The image sensor according to claim 2, wherein the first micro lens comprises thermal resin.

4. The image sensor according to claim 1, wherein the first micro lens comprises:
a first seed micro lens; and
thermal resin on the first seed micro lens.

5. The image sensor according to claim 1, wherein the first dielectric layer has a height corresponding to a first metal line.

6. The image sensor according to claim 2, wherein the first micro lens comprises:
a first seed micro lens; and
thermal resin on the first seed micro lens.

7. The image sensor according to claim 2, wherein the first dielectric layer has a height corresponding to a first metal line.

8. A method for manufacturing an image sensor comprising:
forming a device isolating layer and a photodiode on a substrate;
forming a first dielectric layer on the photodiode;
forming a first micro lens on the first dielectric layer;
forming a second dielectric layer on the first micro lens;
forming a color filter on the second dielectric layer; and
forming a second micro lens on the color filter.

9. The method according to claim 8, wherein the first micro lens comprises an organic material.

10. The method according to claim 9, wherein the first micro lens comprises thermal resin.

11. The method according to claim 10, wherein the forming the first micro lens comprises:
forming a first seed micro lens by selectively etching the first inter metal dielectric;
forming the thermal resin on the first seed micro lens; and
performing a heat treatment on the thermal resin.

12. The method according to claim 8, wherein the first dielectric layer has a height corresponding to the first metal line.

13. The method according to claim 11, wherein the first dielectric layer has a height corresponding to the first metal line.

14. The method according to claim 8, wherein the first micro lens comprises thermal resin.

15. The method according to claim 14, wherein the forming the first micro lens comprises:
forming a first seed micro lens by selectively etching the first inter metal dielectric;
forming the thermal resin on the first seed micro lens; and
performing a heat treatment on the thermal resin.
